(19) United States
(12) Patent Application Publication
(10) Pub. No.: US 2006/0163563 A1
(43) Pub. Date: Jul. 27, 2006

(54) Method to form a thin film resistor

(76) Inventors: Kurt Ulmer, Corvallis, OR (US); Tim Emmerich, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/042,604

(22) Filed: Jan. 24, 2005

(51) Int. Cl. H01L 29/08; H01L 21/20

(52) U.S. Cl. 257/40; 438/141; 977/712

(57) ABSTRACT

Embodiments of methods, apparatuses, devices, and/or systems for forming thin film resistor are described.

### BACKGROUND

Electronic devices, such as laptop computers, pagers, cellular phones, personal data assistants (PDAs) and printing devices, for example, may be comprised of one or more electronic components, which may be thin film components. Thin film components suitable for use in devices such as these may include thin film resistors, for example, and thin film resistors such as these may be formed from varying materials, and may be formed by use of varying methods. However, presently used methods utilized to form thin film resistors may have particular disadvantages. For example, use of such methods may be time-consuming, expensive, or may not produce components and/or devices having the desired characteristics.

### BRIEF DESCRIPTION OF THE DRAWINGS

Subject matter is particularly pointed out and distinctly claimed in the concluding portion of the specification. Claimed subject matter, however, both as to organization and method of operation, together with objects, features, and advantages thereof, may best be understood by reference of the following detailed description when read with the accompanying drawings in which:

FIG. 1 is a cross sectional view of a thin film component in accordance with one embodiment;

FIG. 2 is a schematic diagram of a system suitable for forming a thin film component in accordance with one embodiment;

FIG. 3 is a flowchart illustrating one embodiment of a method to form a thin film component;

FIG. 4 is a flowchart illustrating one embodiment of a method to form a thin film component; and

FIG. 5 illustrates one or more characteristics of a component such as the component illustrated in FIG. 1.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail so as not to obscure claimed subject matter.

Electronic devices, such as laptop computers, pagers, cellular phones, personal data assistants (PDAs), displays, including flexible displays and printing devices, for example, may be comprised of printed electronics. The printed electronics may, for example, include one or more thin film resistors. These thin film resistors may comprise one or more thin films of one or more materials, which may be formed in combination with one or more other materials or a substrate, or various combinations thereof to produce a thin film resistor having desired characteristics, such as electrical characteristics. In this context, the term thin film refers to a layer of one or more materials formed to a thickness, such that the surface properties of the one or more materials may be observed, and these properties may vary from bulk material properties. Alternatively, the one or more thin films of a particular resistor may be referred to as component layers, and, in this context, one or more component layers may comprise one or more layers of material, which may be referred to as material layers, for example. The one or more material or component layers, or combinations thereof may have electrical, physical, and chemical properties, such as resistivity, conductivity, flexibility, chemical interface properties, charge flow, and processability, for example, and may be selectively combined in order to produce a component having a desired resistivity, conductivity, and/or flexibility, as just an example. The one or more material or component layers or both may additionally be patterned, for example, and in combination with one or more other material and/or component layers may form one or more thin film resistors, which may additionally be referred to as composite resistors, for example. Thin film resistors such as these may be utilized in devices that may incorporate embedded circuits and/or printed electronics, and the devices may be portable and/or battery powered, for example, although, of course, the claimed subject matter is not limited in this respect.

At least as part of the fabrication process of a thin film resistor, one or more materials may be deposited on a substrate, such as to form at least a portion of a material layer and/or a component layer of a thin film resistor. A material layer, in this context, may comprise one or more materials, such as a plurality of materials, and a component layer may comprise one or more material layers, for example. The one or more materials of the material and/or component layer may be deposited by use of one or more ejection mechanisms, ejection deposition methods or combinations thereof, and the material(s) may be in one or more forms when deposited. After deposition, the one or more materials may be processed, such as by being patterned, cured or both, for example. The particular processing may depend on the particular material(s), deposition methods and/or form of the material(s) deposited, for example. In at least one embodiment, one material layer may be deposited on or over a substrate by use of an ejection mechanism such as an ink jet device, and may be processed prior to the deposition of subsequent material layers, for example. Alternatively, multiple material layers may be deposited or over a substrate, such as by one or more ejection deposition processes. At least a portion of the multiple material layers may be processed, such as in a single curing step, for example. In at least one embodiment, a thin film resistor may include multiple materials wherein at least a portion of the materials may exhibit particular electrical characteristics, such as particular conductivity and/or resistivity, and differing materials may have differing properties. For example, one material exhibiting a high conductivity or low resistivity, or both, and another material exhibiting low conductivity and/or being highly insulative, or high resistivity or both, such as if the thin film resistor comprises at least two materials, as just an example. Additionally, wherein a thin film resistor is formed to have multiple material layers, which may comprise the same material or varying materials, for example, the multiple material layers may each be deposited by use of the same or varying deposition processes and/or devices. However, particular methods, materials and devices may be better illustrated with reference to the accompanying figures, explained in more detail below.

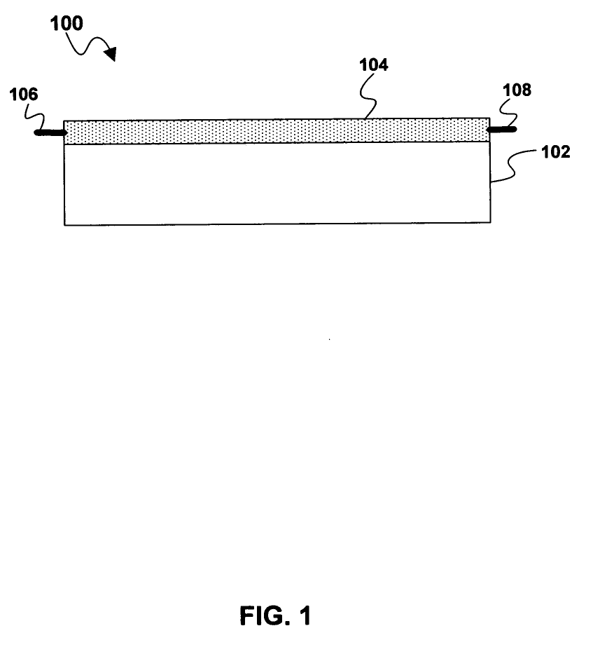

Referring now to FIG. 1, there is illustrated a cross-sectional view of one embodiment 100 of an electronic component in a stage of formation. Electronic component 100, here, may comprise a thin film resistor, for example. Component 100 may be formed by use of one or more processes and/or materials, for example, and may comprise a portion of an electronic device, such as explained previously. Component 100 may comprise a substrate 102, a component layer 104, and leads 106 and 108, which may comprise electrical leads, and/or portions of a trace, such as a conductive trace of a circuit board, for example. However, the claimed subject matter is not limited to this particular configuration. The particular configuration explained herein is primarily for illustrative purposes, and a resistor formed in this manner may not necessarily be formed to have electrical leads, for example. In addition, in this embodiment, component 100, particularly component layer 104, when formed, may have particular electrical, physical and chemical characteristics, and may, for example, exhibit a particular resistivity and/or conductivity between leads 106 and 108. Component layer 104 may be comprised of a single material layer or multiple material layers, which may each be comprised of one or a combination of materials, for example. For example, a combination of two or more materials that may exhibit varying properties, such as varying resistivity, conductivity or both may be combined, such as prior to deposition and/or during the deposition process to form one or more material layers. The material layers also may comprise multiple layers of substantially the same material, for example. Additionally, although not illustrated, multiple component layer portions may be formed on substrate 102, such as to form a plurality of thin film resistors on substrate 102, which may comprise circuitry of an electronic component, for example, and the plurality of thin film resistors may have varying resistance values, explained in more detail later. Additionally, it is noted, of course, here and throughout this description that claimed subject matter is not limited to this particular configuration, and in one or more alternative embodiments, other layers not illustrated in FIG. 1 may be included, such as between, on and/or over substrate 102 and resistive layer 104, for example, and may depend, for example, on the particular embodiment. Additionally, although not illustrated, multiple component layer portions may be formed on substrate 102, such as to form circuitry of an electronic component, for example.

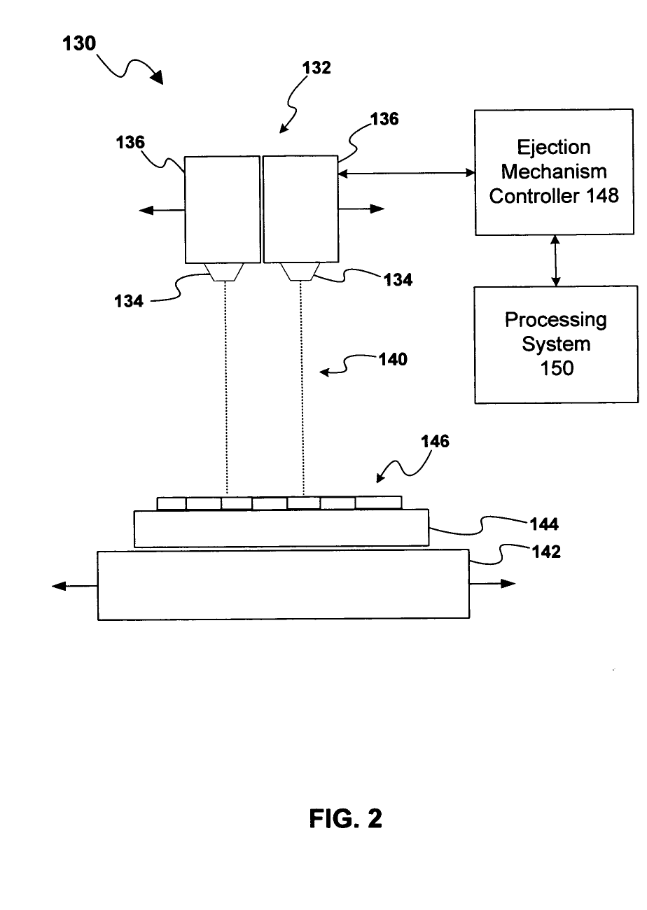

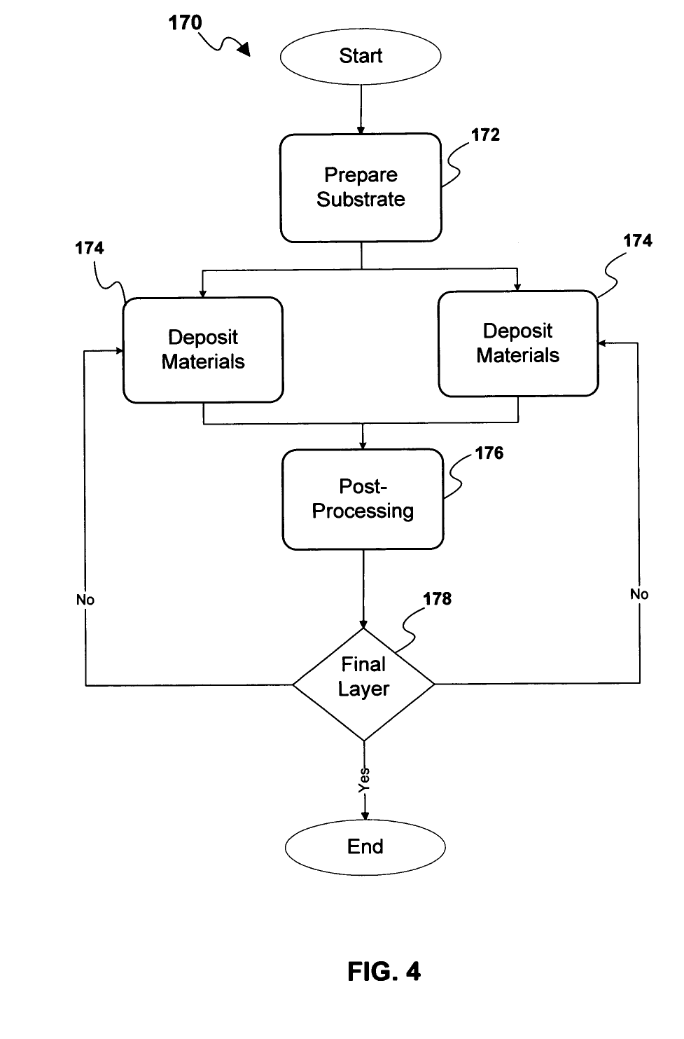

The material layers of FIG. 1 may be formed by use of one or more deposition processes. If multiple material layers are formed, the material layers may be deposited by use of multiple deposition operations, which may vary, for example. In at least one embodiment, wherein the material layers comprise a combination of materials, the materials may combined prior to deposition, such as by mixing, and/or may be deposited at substantially the same time from differing sources, such that the materials may be at least partially mixed on the substrate, for example. In one embodiment, a single deposition mechanism, such as an ejection mechanism may be capable of depositing the multiple materials at substantially the same time and/or sequentially on or over the substrate, such that at least a portion of the materials may be mixed, for example. The resulting component layer may have one or more electrical characteristics, such as a particular conductivity and/or resistivity, and the particular electrical characteristics may depend on the two or more materials used to form the component layer, and/or the relative portions of each component material, for example, which will be explained in more detail with reference to FIG. 4. Alternatively, two or more materials having differing properties may be mixed, and may be deposited on a substrate to form a material layer comprising the mixed materials, for example. However, particular details regarding the formation of a component such as component 100 may be better understood with reference to FIG. 2, explained in more detail later.

Although claimed subject matter is not limited to any particular material or combination of materials to form one or more of the layers and/or components illustrated in FIG. 1, in at least one embodiment, one or more of the component layers may comprise one or more of the materials described below. Additionally, it is worthwhile to note that claimed subject matter is not limited in this respect, and one or more of the component layers may comprise any material or combination of materials exhibiting properties suitable for application as one or more component layers in an electronic component, for example. However, in this embodiment, where component layer 102 comprises a substrate layer, component layer 102 may comprise one or more materials suitable for use as a substrate. For example, substrate layer 102 may comprise one or more types of plastic and/or one or more polymeric substrate materials, such as polyimides (PI), including Kapton®, polyethylene terephthalates (PET), polyethersulfones (PES), polyetherimides (PEI), polycarbonates (PC), polyethylenenaphthalates (PEN), acrylics including polymethylmethacrylates (PMMA), and combinations thereof, but claimed subject matter is not so limited. Additionally, substrate layer 102 may also comprise one or more inorganic materials, including silicon, silicon dioxide, one or more types of glass, stainless steel and metal foils, including foils of aluminum and copper and combinations thereof, for example, but claimed subject matter is not so limited. Additionally, in at least one embodiment, wherein a substrate material is substantially comprised of one or more metals, an insulator layer may be utilized in addition to the one or more metals to form the substrate. Additionally, resistive layer 104 may be comprised of one or more materials, such as a plurality of materials that may be formed in layers, and/or combined, such as during or prior to deposition, for example, and may comprise materials having varying electrical properties, such as varying conductivity and/or resistivity. In this embodiment, the materials may be combined to produce a component having desired electrical characteristics, such as a desired resistance. In this manner, a thin film resistor may be formed wherein the thin film resistor may be configured during formation to have desired properties. For example, in at least one embodiment, resistive layer 104 may comprise at least one material capable of exhibiting conductive properties, such as by exhibiting a low resistivity. In this embodiment, materials exhibiting conductive properties may include one or more metals, and/or one or more oxides, such as conducting oxides, for example, such as one or more of: indium tin oxide (ITO), vanadium oxide, rhenium oxide, other doped oxide semiconductors and compounds such as indium oxide and tin oxide, indium aluminum oxide, lithium vanadium oxide, copper iodide and/or conductive organic materials such as polyethylenethiophene and its derivatives, including PEDOT, and/or metals such as Al, Ag, In, Sn, Zn, Ti, Mo, Au, Pd, Pt, Cu, W, Ni, and combinations thereof, as just a few examples. Additionally, resistive layer 104 may comprise at least one material capable of exhibiting insulative properties, such as zirconia, for example, and/or may include aluminum oxide, silicon dioxide, titanium dioxide, tungsten trioxide, tantalum pentoxide, zinc oxide and/or insulative organic materials such as polyesters, polyvinyls, polystyrenes, acrylics, polysulfides, as just a few examples. However, it is worthwhile to note that the claimed subject matter is not limited to a combination of materials in this manner, but may include one or more materials suitable for use as at least a portion of a component layer of a thin film resistor.

Formation of one or more portions of the components of FIG. 1 may comprise one or more processes, and/or numerous process operations, and may incorporate one or more processing systems such as system 130 of FIG. 2. However, in at least one embodiment, one or more solution processes, including one or more ejection processes such as ink jet processes, may be utilized to form one or more portions of a component, such as component 100 of FIG. 1. Solution processing, as used in this context, comprises one or more processes, wherein a solution, such as a substantially liquid solution, a solid, solid-liquid and/or sol-gel liquid precursor that may be at least partially dissolved in a liquid, or a colloidal dispersion may be deposited on or over one or more surfaces, such as on one or more surfaces of a substrate, by use of one or more deposition processes. Electrical components such as thin film resistors that may be at least partially formed by solution processing may be referred to as solution processed components, for example. In one embodiment of solution processing, an ejection mechanism, such as an ink jet device, may deposit and/or jet one or more materials onto a surface, in order to substantially form at least a portion of a material layer, for example. Utilization of one or more ejection mechanisms, such as an ink jet component, including a thermal ink jet (TIJ) component, for example, may additionally be referred to as a direct write solution process, as just an example. Additionally, as used herein, an ejection mechanism may comprise a mechanism capable of ejecting material such as liquid material, for example, and may eject material in the form of drops or mist, for example, such as mechanically and/or electrically, and/or in response to electrical signals, and may be capable of ejecting material in controlled portions, in a controlled manner, and/or in controlled directions, for example. Additionally, an ejection mechanism may operate by use of one or more ejection schemes, including piezo ejection, thermal ejection, continuous ejection, acoustic ejection and flex tensioned ejection, and may comprise multiple nozzles, for example, but, again, claimed subject matter is not limited to these examples.

Referring now to FIG. 2, there is illustrated a deposition system 130 that may be utilized to form thin film resistors, such as the thin film resistor illustrated in FIG. 1, for example. Illustrated in FIG. 2 is a deposition system 130, comprising an ejection mechanism 132, platform 142, ejection mechanism controller 148, and a processing system 150. Ejection mechanism 132, which may additionally be referred to as an ink jet head, comprises a plurality of ink jet chambers 136, respectively coupled to nozzles 134, which may additionally be referred to as printheads. Although illustrated as two chambers 136, the ink jet head 132 is not so limited, and may comprise more or less than two chambers, such as if more or less than two materials or combinations of materials are utilized to form a thin film transistor, for example. However, continuing with this embodiment, platform 142 may be configured to hold a substrate, such as one or more substrates as described previously. Platform 142 and/or ink jet head 132 may be capable of actuating in one or more directions, such as relative to each other, for example, and in one embodiment platform 142 may comprise a movable platform capable of actuating or rotating in one or more manners, and may include one or more mechanisms and/or controllers capable of actuating or rotating the platform (not shown). System 130 includes processing system 150, which may perform processing by interacting with and/or directing the actions of one or more components of system 130, to perform various operations, as described in more detail below. Although not illustrated in detail, processing system 150 may comprise at least one processor and one or more memory components, such as Random Access Memory (RAM), Synchronous Dynamic Random Access Memory (SDRAM), and/or Static Random Access Memory (SRAM), for example. System 130, although, again, not illustrated in detail, may further comprise: one or more hard drives; one or more removable media memory components, such as floppy diskettes, compact discs, tape drives; a display, such as a monitor, for example, and/or a user interface device, which may include a keyboard, mouse, trackball, voice-recognition device, and/or any other device that permits a user to input information and receive information. Additionally, one or more portions of system 130 may be controlled by suitable instructions in a software program that is stored and/or executed by processing system 150, for example. Additionally, although not illustrated in detail, system 130 may further comprise a post-deposition processing device, such as a curing device capable of heating at least a portion of a component, including an oven, a hot plate, a UV device and/or a laser capable of generating a laser beam at a frequency in the electromagnetic spectrum and having suitable energy to provide intense localized or “spot” heating, for example (not shown), although this is just one example, and claimed subject matter is not limited in this respect.

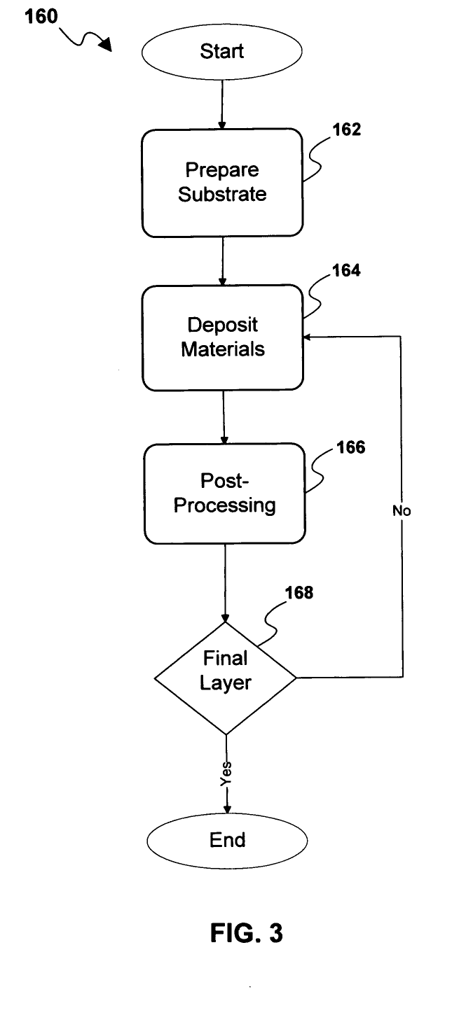

In operation, a substrate, such as substrate 144, which may comprise a substrate substantially similar to substrate 102 of FIG. 1, for example, may be positioned on platform 142. Ink jet head 132 may perform one or more ejection operations, such as by ejecting a single material from each chamber 136, or by ejecting a mixture of two or more materials from a single chamber or printhead, and the ejection may be at least partially initiated and/or controlled by ejection mechanism controller 148 and/or processing system 150. In at least one embodiment, platform 142 and ink jet head 132 may actuate or move relative to one another, which may cause material 140 to be formed on to one or more locations of substrate 144. The material ejected from each chamber 136 by use of nozzles 134 may comprise one or more of the materials as described previously, such as one or more differing materials exhibiting varying resistive and/or conductive characteristics. The materials may be ejected at substantially the same time from chambers 136, which may result in the materials being substantially mixed when deposited on substrate 144. Alternatively, a mixture of two or more materials may be deposited in a mixed state from a single printhead. This may result in the formation of one or more components 146, which may comprise a combination of the materials ejected from ink jet head 132, for example. In at least one embodiment, at least a portion of components 146 may comprise thin film resistors, for example, and may have one or more electrical characteristics that may depend on the particular materials and/or relative portions of materials utilized to form the components 146. For example, in one embodiment, one chamber 136 may contain a material exhibiting a high conductivity, and one chamber 136 may contain a material exhibiting a high resistivity, for example. In this embodiment, for example, when each material is deposited on substrate 144, a plurality of components 146 may be formed that have one or more resistive values, such as differing resistivities, which may be desirable in a thin film resistor application. Additionally, in one embodiment, one or more components 146 may have varying electrical characteristics, and these characteristics may be varied by altering the relative portions of materials 140 ejected from ink jet head 132, for example, and this altering may be at least partially determined by processing system 150 and/or controller 148, such as in accordance with a schematic layout of a circuit of thin film resistors, for example. The relative portions of materials, which may additionally be referred to as the mixing ratio, may be adjusted in ‘real-time’ or ‘on the fly’, meaning, for example, that adjustments may be made during the deposition process, such as between deposition operations such that differing resistors may be formed with materials having differing mixing ratios. In this manner, a plurality of components, such as thin film resistors may be formed on a substrate, wherein at least a portion of the thin film resistors may have varying electrical characteristics, and the resistors may be formed based on a schematic diagram, and may be at least partially automated, for example. Additional details regarding the formation of one or more thin film resistors such as by use of system 130 may be better understood with reference to FIG. 3, later.

As alluded to previously, when formed, components that comprise a combination of one or more of the aforementioned materials may exhibit particular characteristics. For example, if a component is formed having a resistive layer, such as illustrated in FIG. 1, wherein the resistive layer comprises a combination of one or more materials exhibiting particular electrical characteristics such as particular conductivity and/or resistivity, a resultant component may have particular electrical characteristics, such as a resistivity that may be higher than one of the materials, and lower than another of the materials, for example. This may result in the formation of a component having a particular resistivity, wherein the resistivity may be configured by selection of material(s) and relative portions of materials, for example, such that the component may be utilized as a thin film resistor, for example. The particular resistivity may be varied by varying the materials used, the ratio of the materials used, the methods utilized to deposit the one or more materials, and/or the post processing steps taken for example, and multiple thin film resistors having varying resistance values may be formed by use of the same materials such as on a single substrate, such as by varying the material ratios, for example. This may provide the capability of forming multiple resistors on a single substrate wherein the resistors may have varying electrical properties, as just an example. Thus, use of materials such as described above may result in the formation of a thin film resistor having particular properties, such as resistive properties, including a particular resistivity, such as 50 Ohms, 100 Kilo-ohms, and/or 10 Kilo-Ohms, as just a few examples, and/or use of one or more of the materials may result in the formation of multiple resistors with varying properties, may provide the capability to form lower cost and/or smaller size or thinner components as compared to other components, and/or may result in the formation of a component having particular properties that may be desirable in numerous applications, for example.

Referring now to FIG. 3, one embodiment of a technique for forming a thin film resistor is illustrated by a flowchart, although, of course, claimed subject matter is not limited in scope in this respect. The flowchart illustrated in FIG. 3 may be used to form at least a portion of a component, such as component 100, for example, although claimed subject matter is not limited in this respect. Likewise, the order in which the blocks are presented does not necessarily limit claimed subject matter to any particular order. Additionally, intervening blocks not shown may be employed without departing from the scope of claimed subject matter.

Flowchart 160 depicted in FIG. 3 may, in alternative embodiments, be at least partially implemented in a combination of hardware and software and/or firmware, such as the aforementioned computer controlled formation system, for example, and may comprise discrete and/or continual operations. In this embodiment, at block 162, a substrate may be prepared, which may include cleaning and/or processing of the surface of the substrate, for example. At block 164, one or more materials may be disposed on or over at least a portion of a substrate, such as a mixture comprising two or more materials that may be combined prior to deposition, and deposited by use of an ink jet head, such as at least a portion of layer 104 of FIG. 1, for example. In this embodiment, at block 166, one or more post-processing operations may be performed on at least a portion of the substrate and/or material(s) deposited at block 164, for example, although, in alternative embodiments, no post-processing may be performed until the component layer materials are completely deposited, for example. At block 168, a determination may be made whether the material(s) deposited at block 164 were the final layer being deposited to form the component. If the final layer was deposited, the formation process may be substantially complete. However, if additional material(s) are to be deposited, one or more additional materials may be deposited at block 164. After deposition, at block 166, one or more additional post-processing operations may be performed on at least a portion of the additional material(s) deposited at blocks 164, such as by curing and/or patterning at least a portion of the component, for example. The deposition and curing may be repeated until a plurality of material layers are formed, and the plurality of material layers may, when formed, form a component layer of a thin film resistor, such as resistor 100 of FIG. 1.

In this embodiment, at block 162, at least a portion of a substrate may be prepared, such as a substrate substantially comprising one or more materials suitable for use as a substrate, including one or more of the materials described previously. In at least one embodiment, preparing the substrate may comprise cleaning the substrate, such as by washing, for example, and/or may comprise depositing one or more materials on the substrate. Additionally, preparing the substrate may comprise processing the surface of the substrate such that a desired surface roughness or surface finish may be obtained, to improve adhesion of subsequently deposited layers, and/or to reduce deleterious chemical interactions with subsequently deposited layers, and/or altering the substrate chemically or with a laser or UV process, such as to alter the surface of the substrate from a hydrophilic to a hydrophobic state or from a hydrophobic to a hydrophilic state, although, of course, claimed subject matter is not so limited. Additionally, in at least one embodiment, no substrate preparation may be performed, and selection of particular preparations of a substrate surface may depend at least in part on the particular material or combination of materials selected to form a substrate. In one particular example, a substrate, such as a substrate substantially comprising plastic may be prepared. In this example embodiment, the substrate may be cleaned, for example, prior to the deposition of one or more materials. However, as mentioned previously, the claimed subject matter is not limited in this respect.

At block 164, one or more materials may be disposed on or over at least a portion of a substrate, such as a mixture of materials, to form one or more layers, such as one or more material layers of component layer 104, for example. This may comprise depositing a mixture comprising one or more of the aforementioned materials by use of one or more of the aforementioned processes, and may incorporate a deposition system such as system 130 of FIG. 2. In at least one embodiment, a plurality of materials may be deposited by an ink jet device, and the materials may be combined prior to deposition and provided to a chamber of an ejection device, such as ink jet head 132 of FIG. 2, and the materials may have varying conductivity and/or resistivity, such as one material having a relatively high conductivity, and one material having a relatively high resistivity, for example. The selection of the materials and/or the relative portions may depend on the properties desired in the resultant component. In at least one embodiment, Ag may be in one or more forms, such as in a nanoparticle form, and, in this embodiment, may be diluted in 2-isopropanol to form a nanoparticle solution, for example, although, of course, the claimed subject matter is not so limited. However, in this embodiment, the solution may comprise approximately 10% by weight of Ag, for example. The nanoparticle solution may be combined with one or more materials having one or more insulative properties, such as zirconia, which may comprise a solution having nanoparticles of zirconia diluted in 2-isopropanol. The resultant combination may contain varying portions of the Ag and zirconia, and may be deposited by use of system 130, for example. In this embodiment, the zirconia may comprise a particular ratio of the mixture with respect to the 2-isopropanol, such as a 1 to 4 ratio, as just an example.

In this embodiment, at block 166, at least a portion of the material(s) deposited at block 164 may be at least partially post-processed. This may comprise one or more patterning and/or curing processes, for example, and particular selection of a post-processing operation may depend at least in part on the material(s) deposited, and/or the particular deposition processes, for example. However, in at least one embodiment, at least a portion of the material(s) deposited may be cured. This may comprise utilizing a post-deposition processing device capable of heating and/or curing at least a portion of a component, including an oven, a hot plate, and/or a laser capable of generating a laser beam, and/or a UV device capable of generating UV radiation. For example, a hot plate may be utilized to elevate the temperature of at least a portion of the deposited material(s), such as by elevating the material(s) to approximately 200 degrees Celsius, for example, and this may cause one or more organic components of a deposited solution to evaporate, for example. Alternatively, one or more patterning processes may be performed, and this may comprise selectively altering and/or removing at least a portion of the deposited material, such as to form material having a particular shape and/or configuration, for example. In at least one embodiment, patterning may be performed by etching, dissolving, lift-off, laser ablation, direct deposition patterning via inkjet, or other processes resulting in the removal of at least a portion of the material(s), for example. However, selection of particular patterning processes may depend at least in part on the particular material(s) selected to form the material layer, for example. Additionally, no post processing may be performed, if, for example, the one or more materials deposited do not necessitate the use of one or more post processes, for example.

At block 168, a determination may be made whether the layer deposited at block 164 was the final layer of a component being formed. If the final layer was formed, the formation process may be substantially complete. However, if the layer deposited was not the final layer, one or more additional layers of the materials may be deposited at block 164, and post processes at block 166. This process may be repeated one or more times to form one or more material layers of a component, such as if the component comprises multiple sub-layers, for example. The material layers may be formed to a particular thickness, and the layers may be deposited incrementally until a desired component layer thickness is obtained, for example. Additionally, one or more of the foregoing operations may be repeated, such as to form one or more additional components, such as a plurality of thin film resistors on the same substrate, wherein the thin film resistors may have component layers with varying thicknesses, for example. In this manner, circuitry comprising a plurality of thin film resistors may be formed on a single substrate, as just an example.

Referring now to FIG. 4, one embodiment of a technique for forming a thin film resistor is illustrated by a flowchart, although, of course, claimed subject matter is not limited in scope in this respect. The flowchart illustrated in FIG. 4 may be used to form at least a portion of a component, such as component 100 of FIG. 1, for example, although claimed subject matter is not limited in this respect. Likewise, the order in which the blocks are presented does not necessarily limit claimed subject matter to any particular order. Additionally, intervening blocks not shown may be employed without departing from the scope of claimed subject matter.

Flowchart 170 depicted in FIG. 4 may, in alternative embodiments, be at least partially implemented in a combination of hardware and software and/or firmware, such as the aforementioned computer controlled formation system, for example, and may comprise discrete and/or continual operations. In this embodiment, at block 172, a substrate may be prepared, which may include cleaning and/or processing of the surface of the substrate, for example. At block 174, multiple materials may be disposed on or over at least a portion of a substrate, such as two materials deposited by use of a dual chamber ink jet head, wherein the materials may be disposed at substantially the same time to form one or more layers, such as at least a portion of layer 104 of FIG. 1, for example. In this embodiment, at block 176, one or more post-processing operations may be performed on at least a portion of the substrate and/or material(s) deposited at block 174, for example, although, in alternative embodiments, no post-processing may be performed until the component layer materials are completely deposited, for example. At block 178, a determination may be made whether the material(s) deposited at block 174 were the final layer being deposited to form the component. If the final layer was deposited, the formation process may be substantially complete. However, if additional material(s) are to be deposited, one or more additional materials may be deposited at block 174. After deposition, at block 176, one or more additional post-processing operations may be performed on at least a portion of the additional materials deposited at blocks 174, such as by curing and/or patterning at least a portion of the component, for example. The deposition and curing may be repeated until a plurality of material layers are formed, and the plurality of material layers may, when formed, form a component layer of a thin film resistor, such as resistor 100 of FIG. 1.

In this embodiment, at block 172, at least a portion of a substrate may be prepared, such as a substrate substantially comprising one or more materials suitable for use as a substrate, including one or more of the materials described previously. In at least one embodiment, preparing the substrate may comprise cleaning the substrate, such as by washing, for example, and/or may comprise depositing one or more materials on the substrate. Additionally, preparing the substrate may comprise processing the surface of the substrate such that a desired surface roughness or surface finish may be obtained, to improve adhesion of subsequently deposited layers, and/or to reduce deleterious chemical interactions with subsequently deposited layers, and/or altering the substrate chemically or with a laser or UV process, such as to alter the surface of the substrate from a hydrophilic to a hydrophobic state or from a hydrophobic to a hydrophilic state, although, of course, claimed subject matter is not so limited. Additionally, in at least one embodiment, no substrate preparation may be performed, and selection of particular preparations of a substrate surface may depend at least in part on the particular material or combination of materials selected to form a substrate. In one particular example, a substrate, such as a substrate substantially comprising plastic may be prepared. In this example embodiment, the substrate may be cleaned, for example, prior to the deposition of one or more materials. However, as mentioned previously, the claimed subject matter is not limited in this respect.

At block 174, materials may be disposed on or over at least a portion of a substrate, such as to form one or more layers, such as one or more layers of component layer 104, for example. This may comprise depositing one or more of the aforementioned materials by use of one or more of the aforementioned processes, and may incorporate a deposition system such as system 130 of FIG. 2. In at least one embodiment, a plurality of materials may be deposited by an ink jet device having two or more ink chambers and/or nozzles, such as ink jet head 132 of FIG. 2, and the materials may have varying conductivity and/or resistivity, such as one material having a relatively high conductivity, and one material having a relatively high resistivity, for example. In at least one embodiment, Ag may be deposited by one chamber 136 and nozzle 134 of system 130, and may be in one or more forms, such as in a nanoparticle form, and, in this embodiment, may be diluted in 2-isopropanol to form a nanoparticle solution, for example, although, of course, the claimed subject matter is not so limited. However, in this embodiment, the solution may comprise approximately 10% by weight of Ag, for example. The nanoparticle solution may be deposited in controlled portions and/or to a controlled thickness, such as to form at least a portion of one or more layers of component layer 104, for example. Alternatively, the Ag may be in one or more forms other than a nanoparticle form, and the particular form may depend at least in part on the device utilized to deposit the material, for example. Additionally, one or more materials having one or more insulative properties may be deposited, such as at substantially the same time as the Ag, for example. In one embodiment, the aforementioned zirconia, which may comprise a solution having nanoparticles of zirconia diluted in 2-isopropanol may be deposited by use of system 130, for example. In this embodiment, the zirconia may be diluted to have a particular ratio with respect to the 2-isopropanol, such as a 1 to 4 ratio, as just an example. Additionally, the Ag and zirconia may be respectively contained in the two chambers 136, and may be deposited at substantially the same time. Alternatively, a particular portion of Ag may be deposited, and a particular portion of zirconia may be deposited, such as incrementally, and this process may be repeated until a material and/or component layer is formed to a desired thickness, and, in this embodiment, at least a portion of the two materials may be mixed when deposited on to the substrate, for example.

In this embodiment, at block 176, at least a portion of the material(s) deposited at block 174 may be at least partially post-processed. This may comprise one or more patterning and/or curing processes, for example, and particular selection of a post-processing operation may depend at least in part on the material(s) deposited, and/or the particular deposition processes, for example. However, in at least one embodiment, at least a portion of the material(s) deposited may be cured. This may comprise utilizing a post-deposition processing device capable of heating and/or curing at least a portion of a component, including an oven, a hot plate, and/or a laser capable of generating a laser beam, and/or a UV device capable of generating UV radiation. For example, a hot plate may be utilized to elevate the temperature of at least a portion of the deposited material(s), such as by elevating the material(s) to approximately 200 degrees Celsius, for example, and this may cause one or more organic components of a deposited solution to evaporate, for example. Alternatively, one or more patterning processes may be performed, and this may comprise selectively altering and/or removing at least a portion of the deposited material, such as to form material having a particular shape and/or configuration, for example. In at least one embodiment, patterning may be performed by etching, dissolving, lift-off, laser ablation, direct deposition patterning via inkjet, or other processes resulting in the removal of at least a portion of the material(s), for example. However, selection of particular patterning processes may depend at least in part on the particular material(s) selected to form the material layer, for example. Additionally, no post processing may be performed, if, for example, the one or more materials deposited do not necessitate the use of one or more post processes, for example.

At block 178, a determination may be made whether the layer of materials deposited at block 174 was the final layer of a component being formed. If the final layer was formed, the formation process may be substantially complete. However, if the layer deposited was not the final layer, additional layers of the materials may be deposited at block 174, and post processed at block 176. This process may be repeated one or more times to form one or more material layers of a component, such as if the component comprises multiple sub-layers, for example. The material layers may be formed to a particular thickness, and the layers may be deposited incrementally until a desired component layer thickness is obtained, for example. Additionally, one or more of the foregoing operations may be repeated, such as to form one or more additional components, such as a plurality of thin film resistors on the same substrate, wherein the thin film resistors may have component layers with varying thicknesses, for example. In this manner, circuitry comprising a plurality of thin film resistors may be formed on a single substrate, as just an example. Additionally, one or more of the foregoing operations may be repeated, such as to form one or more additional components, such as a plurality of thin film resistors on the same substrate, wherein the thin film resistors may have varying electrical characteristics that may be determined by altering the relative portions of the materials deposited at blocks 174, for example. In this embodiment, a plurality of thin film resistors may be formed that have differing resistivities, which may be desirable in a thin film resistor application. The resistivities may be varied between resistors by altering the relative portions of materials ejected at block 174, for example, and, as stated previously, the mixing ratio, may be adjusted in ‘real-time’ or ‘on the fly’, such that differing resistors may be formed with materials having differing mixing ratios. In this manner, a plurality of components, such as thin film resistors may be formed on a substrate, wherein at least a portion of the thin film resistors may have varying electrical characteristics, and the resistors may be formed based on a schematic diagram, and may be at least partially automated, for example.

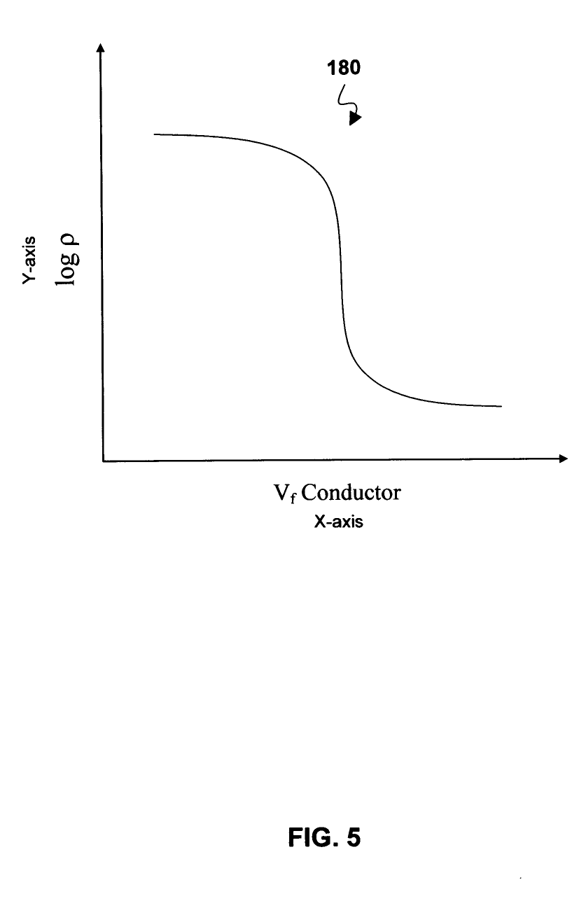

Referring now to FIG. 5, there is illustrated a graph 180, which may illustrate one or more characteristics of a component such as the component illustrated in FIG. 1 for example. Illustrated in FIG. 5 is graph 180, which demonstrates one or more electrical characteristics of a component, such as a thin film resistor that may be formed by use of one or more of the foregoing materials and/or processes, for example. Graph 180 comprises an x-axis V_{f} conductor, which comprises volume fraction of conductive material in a mixture comprising conductive and insulative components, such as conductive material in a matrix of insulative material. The y-axis of graph 180, log ρ comprises the log of resistivity. Graph 180 demonstrates that as the volume fraction of conductive material in a component such as a thin film resistor increases, resistivity may decrease, and a desired resistivity of a component may be obtained by forming a component having a particular ratio of conductive to insulative material, such as by utilizing one or more of the methods, materials, and/or devices of formation described and illustrated above. Additionally, from graph 180, it is illustrated that the resistance of a component having a conductive portion may vary greatly with an incremental change in volume fraction of conductivity, and utilization of an ink jet device such as illustrated in system 130 may provide the capability to fabricate a resistor having a particular resistivity by minutely varying the ratio of conductive and insulative materials, for example.

As alluded to previously, formation of one or more material and/or component layers in the foregoing manner and/or by use of one or more of the foregoing materials and/or systems may result in the formation of an electronic component and/or an electronic device having particular characteristics that may vary from a component not being formed in this manner and/or from this particular combination of materials. For example, thin film resistors may be formed in this manner, and may result in the formation of multiple thin film resistors with varying properties, such as circuitry that may comprise multiple resistors, and the resistors may be formed by varying the mixing ratio of materials used to form the material layers. The mixing ratio may be adjusted in ‘real-time’ or ‘on the fly’ by use of a system 130, for example, and the resistors may have particular properties, such as desirable resistive properties, and/or may be formed from a variety of processes and/or materials, and may be lower cost and/or smaller size as compared to other components, and/or may have particular properties that may be desirable in numerous applications, including one or more resistivity values, such as 50 Ohms, 100 Kilo-ohms, and/or 10 Kilo-Ohms, as just a few examples.

It is, of course, now appreciated, based at least in part on the foregoing disclosure, that a combination of hardware in combination with software and/or firmware may be produced capable of performing a variety of operations, including one or more of the foregoing operations, which may be implemented in a system suitable for forming a thin film resistor, as described previously. It will additionally be understood that, although particular embodiments have just been described, claimed subject matter is not limited in scope to a particular embodiment or implementation. For example, a system capable of implementing one or more of the foregoing operations described in reference to FIG. 2 may comprise hardware, such as implemented to operate on a device or combination of devices as previously described, for example, whereas another embodiment may be in software and hardware, for example. Likewise, an embodiment of a system capable of implementing one or more of the abovementioned operations may be implemented in firmware, or as any combination of hardware, software, and/or firmware, for example. Additionally, all or a portion of one embodiment may be implemented to operate at least partially in one device, such as an ejection device, a laser device, a display, a computing device, a set top box, a cell phone, and/or a personal digital assistant (PDA), for example. Likewise, although claimed subject matter is not limited in scope in this respect, one embodiment may comprise one or more articles, such as a storage medium or storage media. This storage media, such as, one or more CD-ROMs and/or disks, for example, may have stored thereon instructions, that when executed by a system, such as a computer system, computing platform, a set top box, a cell phone, and/or a personal digital assistant (PDA), and/or other system, for example, may result in an embodiment of a method in accordance with claimed subject matter being executed, such as one of the embodiments previously described, for example. As one potential example, a computing platform may include one or more processing units or processors, one or more input/output devices, such as a display, a keyboard and/or a mouse, and/or one or more memories, such as static random access memory, dynamic random access memory, flash memory, and/or a hard drive, although, again, claimed subject matter is not limited in scope to this example.

In the preceding description, various aspects of claimed subject matter have been described. For purposes of explanation, specific numbers, systems and/or configurations were set forth to provide a thorough understanding of claimed subject matter. However, it should be apparent to one skilled in the art having the benefit of this disclosure that claimed subject matter may be practiced without the specific details. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all such modifications and/or changes as fall within the true spirit of claimed subject matter.

1. A method, comprising:
depositing by a solution process a first material over at least a portion of a substrate such as to form a first portion of a component layer of a thin film resistor, wherein at least a portion of said first material is at least partially conductive;
depositing by a solution process a second material over at least a portion of a substrate such as to form a second portion of a component layer of a thin film resistor, wherein at least a portion of said second material is at least partially insulative, and wherein said first and said second materials are deposited substantially simultaneously.

2. The method of claim 1, wherein said first and said second materials are deposited in a ratio such as to form a component layer of a thin film resistor having a particular resistivity.

3. The method of claim 1, and further comprising:
substantially repeating said depositing of said first and said second materials, such as to form a component layer comprising multiple material layers.

4. The method of claim 3, wherein said first and said second materials are deposited by one or more solution processes, including: an ejection process, a spin coating process, a contact printing process, a dip-coating process, a spray coating process, or a chemical bath deposition process.

5. The method of claim 4, wherein said first and said second material are deposited by an ejection mechanism.

6. The method of claim 5 wherein said ejection mechanism comprises an ink jet device.

7. The method of claim 6, wherein said ink jet device comprises a thermal ink jet (TIJ) device.

8. The method of claim 1, wherein said at least partially conductive material substantially comprises one or more of: indium tin oxide (ITO), vanadium oxide, rhenium oxide, indium oxide, tin oxide, indium aluminum oxide, lithium vanadium oxide, copper iodide, polyethylenethiophene and its derivatives, including PEDOT, Al, Ag, In, Sn, Zn, Ti, Mo, Au, Pd, Pt, Cu, W, Ni, and combinations thereof.

9. The method of claim 1, wherein said at least partially insulative material substantially comprises one or more of: zirconia, aluminum oxide, silicon dioxide, titanium dioxide, tungsten trioxide, tantalum pentoxide, zinc oxide, polyesters, polyvinyls, polystyrenes, acrylics, polysulfides and combinations thereof.

10. The method of claim 1, wherein the substrate substantially comprises one or more of: plastics, polyimides (PI), polyethylene terephthalates (PET), polyethersulfones (PES), polyetherimides (PEI), polycarbonates (PC), polyethylenenaphthalates (PEN), acrylics including polymethylmethacrylates (PMMA), silicon, silicon dioxide, one or more types of glass, metal foils, and combinations thereof.

11. The method of claim 8, wherein said at least partially conductive material substantially comprises a solution comprising nanoparticles of Ag suspended in a solvent of 2-isopropanol, wherein said nanoparticles of Ag comprise approximately 10% of said solution by weight.

12. The method of claim 9, wherein said at least partially insulative material substantially comprises a zirconia in a sol-gel precursor form.

13. A method, comprising:
depositing by one or more solution processes two or more materials onto a substrate at substantially the same time to form at least a portion of a thin film, wherein one of said two or more materials is substantially insulative, and one of said two or more materials is substantially conductive, and wherein said two or more materials are deposited from differing material sources.

14. The method of claim 13, wherein said first and said second materials are deposited in a ratio such as to form a component layer of a thin film resistor having a particular resistivity.

15. The method of claim 13, wherein at least a portion of said two or more materials are deposited by use of two or more solution processes.

16. The method of claim 15, wherein said depositing of said two or more materials are performed by differing solution processes.

17. The method of claim 15, wherein at least one of said two or more solution processes comprise: an ejection process, a spin coating process, a contact printing process, a dip-coating process, a spray coating process, or a chemical bath deposition process.

18. The method of claim 17, wherein said ejection mechanism comprises an ink jet device.

19. The method of claim 18, wherein said ink jet device comprises a thermal ink jet (TIJ) device.

20. The method of claim 13, wherein said at least partially conductive material substantially comprises one or more of: indium tin oxide (ITO), vanadium oxide, rhenium oxide, indium oxide, tin oxide, indium aluminum oxide, lithium vanadium oxide, copper iodide, polyethylenethiophene and its derivatives, including PEDOT, Al, Ag, In, Sn, Zn, Ti, Mo, Au, Pd, Pt, Cu, W, Ni, and combinations thereof.

21. The method of claim 13, wherein said at least partially insulative material substantially comprises one or more of: zirconia, aluminum oxide, silicon dioxide, titanium dioxide, tungsten trioxide, tantalum pentoxide, zinc oxide, polyesters, polyvinyls, polystyrenes, acrylics, polysulfides and combinations thereof.

22. The method of claim 13, wherein substrate substantially comprises one or more of: plastics, polyimides (PI), polyethylene terephthalates (PET), polyethersulfones (PES), polyetherimides (PEI), polycarbonates (PC), polyethylenenaphthalates (PEN), acrylics including polymethylmethacrylates (PMMA), silicon, silicon dioxide, one or more types of glass, metal foils, and combinations thereof.

23. The method of claim 20, wherein said conductive material substantially comprises a solution comprising nanoparticles of Ag suspended in a solvent of 2-isopropanol, wherein said nanoparticles of Ag comprise approximately 10% of said solution by weight.

24. The method of claim 21, wherein said at least partially insulative material substantially comprises a zirconia in a sol-gel precursor form.

25. A method, comprising:
a step for depositing by a solution process a first material over at least a portion of a substrate such as to form a first portion of a component layer of a thin film resistor, wherein at least a portion of said first material is at least partially conductive;
a step for depositing by a solution process a second material over at least a portion of a substrate such as to form a second portion of a component layer of a thin film resistor, wherein at least a portion of said second material is at least partially insulative, and wherein said first and said second materials are ejected substantially simultaneously.

26. The method of claim 25, wherein said first and said second materials are deposited in a ratio such as to form a component layer of a thin film resistor having a particular resistivity.

27. The method of claim 25, wherein said first and said second materials are deposited in a ratio such as to form a component layer of a thin film resistor having a particular resistivity.

28. The method of claim 25, and further comprising:
a step for substantially repeating said steps for depositing said first and said second materials, such as to form a component layer comprising multiple material layers.

29. The method of claim 25, wherein steps for depositing are performed by an ejection mechanism.

30. The method of claim 29, wherein said ejection mechanism comprises an ink jet device.

31. The method of claim 30, wherein said ink jet device comprises a thermal ink jet (TIJ) device.

32. The method of claim 25, wherein said at least partially conductive material substantially comprises one or more of: indium tin oxide (ITO), vanadium oxide, rhenium oxide, indium oxide, tin oxide, indium aluminum oxide, lithium vanadium oxide, copper iodide, polyethylenethiophene and its derivatives, including PEDOT, Al, Ag, In, Sn, Zn, Ti, Mo, Au, Pd, Pt, Cu, W, Ni, and combinations thereof.

33. The method of claim 25, wherein said at least partially insulative material substantially comprises one or more of: zirconia, aluminum oxide, silicon dioxide, titanium dioxide, tungsten trioxide, tantalum pentoxide, zinc oxide, polyesters, polyvinyls, polystyrenes, acrylics, polysulfides and combinations thereof.

34. The method of claim 25, wherein substrate substantially comprises one or more of: plastics, polyimides (PI), polyethylene terephthalates (PET), polyethersulfones (PES), polyetherimides (PEI), polycarbonates (PC), polyethylenenaphthalates (PEN), acrylics including polymethylmethacrylates (PMMA), silicon, silicon dioxide, one or more types of glass, metal foils, and combinations thereof.

35. The method of claim 32, wherein said at least partially conductive material substantially comprises a solution comprising nanoparticles of Ag suspended in a solvent of 2-isopropanol, wherein said nanoparticles of Ag comprise approximately 10% of said solution by weight.

36. The method of claim 33, wherein said at least partially insulative material substantially comprises a zirconia in a sol-gel precursor form.

37. A thin film resistor, formed substantially by a process comprising:
depositing by one or more solution processes two or more materials on to a substrate at substantially the same time to form at least a portion of a thin film resistor, wherein one of said two or more materials is substantially insulative, and one of said two or more materials is substantially conductive, and wherein said two or more materials are deposited from differing material sources.

38. The thin film resistor of claim 37, wherein said first and said second materials are deposited in a ratio such as to form a component layer of a thin film resistor having a particular resistivity.

39. The thin film resistor of claim 37, wherein at least a portion of said two or more materials are deposited by use of two or more solution processes.

40. The thin film resistor of claim 39, wherein said depositing of said two or more materials are performed by differing solution processes.

41. The thin film resistor of claim 39, wherein said one or more solution processes comprise one or more of the following: ejection processes, spin coating processes, contact printing processes, dip-coating processes, spray coating processes, and/or chemical bath deposition processes.

42. The thin film resistor of claim 41, wherein said ejection process is performed by an ink jet device.

43. The thin film resistor of claim 42, wherein ink jet device comprises a thermal ink jet (TIJ) device.

44. The thin film resistor of claim 37, wherein said at least partially conductive material substantially comprises one or more of: indium tin oxide (ITO), vanadium oxide, rhenium oxide, indium oxide, tin oxide, indium aluminum oxide, lithium vanadium oxide, copper iodide, polyethylenethiophene and its derivatives, including PEDOT, Al, Ag, In, Sn, Zn, Ti, Mo, Au, Pd, Pt, Cu, W, Ni, and combinations thereof.

45. The thin film resistor of claim 37, wherein said at least partially insulative material substantially comprises one or more of: zirconia, aluminum oxide, silicon dioxide, titanium dioxide, tungsten trioxide, tantalum pentoxide, zinc oxide, polyesters, polyvinyls, polystyrenes, acrylics, polysulfides and combinations thereof.

46. The thin film resistor of claim 37, wherein substrate substantially comprises one or more of: plastics, polyimides (PI), polyethylene terephthalates (PET), polyethersulfones (PES), polyetherimides (PEI), polycarbonates (PC), polyethylenenaphthalates (PEN), acrylics including polymethylmethacrylates (PMMA), silicon, silicon dioxide, one or more types of glass, metal foils, and combinations thereof.

47. The thin film resistor of claim 44, wherein said conductive material substantially comprises a solution comprising nanoparticles of Ag suspended in a solvent of 2-isopropanol, wherein said nanoparticles of Ag comprise approximately 10% of said solution by weight.

48. The thin film resistor of claim 45, wherein said at least partially insulative material substantially comprises a zirconia in a sol-gel precursor form.

49. A system, comprising:
a deposition mechanism
a platform; and
an actuator, said deposition mechanism, said platform and said actuator being configured to, in operation:
deposit by a solution process a first material of over at least a portion of a substrate in place on the platform such as to form a first portion of a component layer of a thin film resistor, wherein at least a portion of said first material is at least partially conductive;
deposit by a solution process a second material over at least a portion of the substrate such as to form a second portion of a component layer of a thin film resistor, wherein at least a portion of said second material is at least partially insulative, and wherein said first and said second materials are deposited substantially simultaneously; and
actuate said platform and substantially repeat said deposition of said first and second material such as to form a plurality of thin film resistors.

50. The system of claim 49, wherein said first and said second materials are deposited in a ratio such as to form a component layer of a thin film resistor having a particular resistivity.

51. The system of claim 49, wherein said deposition mechanism comprises an ejection mechanism.

52. The system of claim 51, wherein said ejection mechanism comprises a single chamber, multiple single chamber or multi-chamber ink jet device.

53. The system of claim 52, wherein said inkjet mechanism comprises a thermal ink jet (TIJ) mechanism.

54. The system of claim 49, wherein said at least partially conductive material substantially comprises one or more of: indium tin oxide (ITO), vanadium oxide, rhenium oxide, indium oxide, tin oxide, indium aluminum oxide, lithium vanadium oxide, copper iodide, polyethylenethiophene and its derivatives, including PEDOT, Al, Ag, In, Sn, Zn, Ti, Mo, Au, Pd, Pt, Cu, W, Ni, and combinations thereof.

55. The system of claim 49, wherein said at least partially insulative material substantially comprises one or more of: zirconia, aluminum oxide, silicon dioxide, titanium dioxide, tungsten trioxide, tantalum pentoxide, zinc oxide, polyesters, polyvinyls, polystyrenes, acrylics, polysulfides and combinations thereof.

56. The system of claim 49, wherein substrate substantially comprises one or more of: plastics, polyimides (PI), polyethylene terephthalates (PET), polyethersulfones (PES), polyetherimides (PEI), polycarbonates (PC), polyethylenenaphthalates (PEN), acrylics including polymethylmethacrylates (PMMA), silicon, silicon dioxide, one or more types of glass, metal foils, and combinations thereof.

57. The system of claim 49, wherein said at least partially conductive material substantially comprises a solution comprising nanoparticles of Ag suspended in a solvent of 2-isopropanol, wherein said nanoparticles of Ag comprise approximately 10% of said solution by weight.

58. The system of claim 49, wherein said at least partially insulative material substantially comprises a zirconia in a sol-gel precursor form.
